(19) United States
(12) Patent Application Publication
(10) Pub. No.: US 2023/0043562 A1
(43) Pub. Date: Feb. 9, 2023

(54) COLORED RESIN COMPOSITION

(71) Applicant: SUMITOMO CHEMICAL COMPANY, LIMITED, Tokyo (JP)

(72) Inventors: Hirotsugu KANO, Osaka-shi (JP); Takakiyo TERAKAWA, Osaka-shi (JP)

(73) Assignee: SUMITOMO CHEMICAL COMPANY, LIMITED, Tokyo (JP)

(21) Appl. No.: 17/784,096

(22) PCT Filed: Dec. 14, 2020
(86) PCT No.: PCT/JP2020/046471

§ 371 Date: Jun. 9, 2022

(30) Foreign Application Priority Data
Dec. 24, 2019 (JP) 2019-232623

(51) Int. Cl. C08F 2/44; G03F 7/004; C09B 67/22; G02B 5/20; G03F 7/00; H01L 27/32

(52) U.S. Cl. CPC C08F 2/44; G03F 7/004; C09B 67/0033; G02B 5/20; G03F 7/0007; H01L 27/32

(57) ABSTRACT

An object of the present invention is to provide a colored resin composition, which is useful in production of a color filter suitable for an organic EL display device, excellent in low temperature curability, and also excellent in red color reproducibility. The present invention relates to the colored resin composition containing a colorant, a resin, a polymerizable compound, and a polymerization initiator, wherein the colorant is composed of only pigments, and the pigments include C.I. Pigment Violet 19, a red pigment and a yellow pigment.

### TECHNICAL FIELD

The present invention relates to a colored resin composition. Specifically, the present invention relates to a colored resin composition for a red color.

### BACKGROUND ART

An organic EL (Electro-Luminescence) display device using an OLED (Organic Light Emitting Diode) or the like does not require any backlight and thus can be produced lighter or thinner than a liquid crystal display device or the like, can realize a high response speed and high image quality with high contrast, can save power, and can be bent. Therefore, the organic EL display device is used in various fields such as mobile phones, mobile information terminals, and television.

As a colored resin composition for forming a color filter to be used in an organic EL display device, a colored resin composition for a red color with good color reproducibility is required. As an example of the colored resin composition for a red color, a composition containing, as a colorant, C.I. Pigment Violet 19, a red pigment, a yellow pigment, a dye polymer, and C.I. Solvent Orange 62 of Patent Literature 1 is known.

### CITATION LIST

### Patent Literature

Patent Literature 1: Japanese Patent Laid-Open No. 2017-201003

### SUMMARY OF INVENTION

### Technical Problem

An organic light-emitting layer to be used for an organic EL display device has generally low heat resistance. Accordingly, a colored resin composition for forming a color filter to be used for such an organic EL display device is preferably cured at low temperatures such as 130° C. or lower. However, when the composition disclosed in cited document 1 was cured at a low temperature, no good color filter was obtained.

An object of the present invention is to provide a colored resin composition, which is useful in production of a color filter suitable for an organic EL display device, excellent in low temperature curability, and also excellent in red color reproducibility.

### Solution to Problem

The gist of the present invention is as follows.

[1] A colored resin composition containing a colorant, a resin, a polymerizable compound, and a polymerization initiator, wherein the colorant is composed of only a pigment(s), and the pigments include C.I. Pigment Violet 19, a red pigment and a yellow pigment.
[2] The colored resin composition according to [1], containing at least one red pigment selected from C.I. Pigment Red 177, C.I. Pigment Red 254, C.I. Pigment Red 269 and C.I. Pigment Red 291.
[3] The colored resin composition according to [1] or [2], wherein the red pigments include C.I. Pigment Red 269.
[4] The colored resin composition according to any one of [1] to [3], wherein the yellow pigments include C.I. Pigment Yellow 139.
[5] A color filter, which is formed of the colored resin composition according to any one of [1] to [4].
[6] An organic EL display device, containing the color filter according to [5].

### Advantageous Effects of Invention

According to the present invention, a colored resin composition, which is useful in production of a color filter suitable for an organic EL display device, excellent in low temperature curability and further excellent in red color reproducibility can be provided.

### DESCRIPTION OF EMBODIMENTS

The colored resin composition of the present invention contains a colorant, a resin (hereinafter, sometimes referred to as a resin (B)), a polymerizable compound (hereinafter, sometimes referred to as a polymerizable compound (C)) and a polymerization initiator (hereinafter, sometimes referred to as a polymerization initiator (D)), wherein the colorant (A) is composed of only a pigment(s) (hereinafter, sometimes referred to as a pigment(s) (A1)).

Further, the colored resin composition according to the present invention preferably contains a solvent (hereinafter, sometimes referred to as a solvent (E)).

Further, the colored resin composition according to the present invention may contain a polymerization initiation aid (hereinafter, sometimes referred to as a polymerization initiation aid (D1)).

Further, the colored resin composition according to the present invention may contain a leveling agent (hereinafter, sometimes referred to as a leveling agent (F))

Herein, compounds exemplified as components may be used singly or in combinations of a plurality thereof unless otherwise noted.

### <Colorant (A)>

In the colored resin composition according to the present invention, the colorant (A) is composed of only the pigment(s) (A1). The colorant(A) is composed of only the pigment(s) (A1), so that the thus obtained colored resin composition has low temperature curability better than that of a colored resin composition containing also a dye as a colorant.

Note that having better low temperature curability means that a good color filter that is stickiness-free even when cured at low temperatures such as 130° C. or lower is obtained. Further, it is preferable that with the use of the colored resin composition according to the present invention, a color filter excellent in solvent resistance can be formed even when curing is performed at low temperatures above. The term “color filter excellent in solvent resistance” means a color filter exhibiting less changes in color before and after immersion in a solvent.

The colored resin composition according to the present invention contains C.I. Pigment Violet 19, a red pigment and a yellow pigment as the pigment(s) (A1).

Examples of the red pigment include C.I. Pigment Reds 9, 97, 105, 122, 144, 149, 166, 168, 176, 177, 180, 190, 192, 209, 215, 216, 224, 242, 254, 255, 264, 265, 266, 268, 269, and 273. As the red pigments, at least one red pigment selected from C.I. Pigment Reds 177, 254, 269 and 291 is preferably contained, and more preferably C.I. Pigment Red 269 is contained. In the whole amount of the red pigments, preferably C.I. Pigment Reds 177, 254, 269 and/or 291 account(s) for 50% by mass or more, more preferably C.I. Pigment Reds 177, 254, 269 and/or 291 account(s) for 80% by mass or more, still more preferably C.I. Pigment Reds 177, 254, 269 and/or 291 account(s) for the whole amount of the red pigments, and still more preferably C.I. Pigment Red 269 accounts for the whole amount of the red pigment.

Examples of the yellow pigment(s) include C.I. Pigment Yellows 1, 3, 12, 13, 14, 15, 16, 17, 20, 24, 31, 53, 83, 86, 93, 94, 109, 110, 117, 125, 128, 129, 137, 138, 139, 147, 148, 150, 153, 154, 166, 173, 185, 194, 214, and 231. The yellow pigment(s) to be preferably contained is C.I. Pigment Yellow 139, and more preferably C.I. Pigment Yellow 139 accounts for 50% by mass or more, still more preferably C.I. Pigment Yellow 139 accounts for 80% by mass or more in the whole amount of the yellow pigment(s), and still more preferably C.I. Pigment Yellow 139 accounts for the whole amount of the yellow pigment.

The content rate of C.I. Pigment Violet 19 is preferably 5% by mass or more, more preferably 10% by mass or more, still more preferably 13% by mass or more, and still more preferably 15% by mass or more, and is preferably 60% by mass or less, more preferably 55% by mass or less, still more preferably 52% by mass or less, and still more preferably 50% by mass or less in the whole amount of the colorant (A). If the content rate of C.I. Pigment Violet 19 in the colorant (A) is increased, a colored resin composition having good color reproducibility can be obtained.

The content rate of C.I. Pigment Violet 19 is preferably 2% by mass or more, more preferably 5% by mass or more, and still more preferably 8% by mass or more, and is preferably 35% by mass or less, more preferably 30% by mass or less, and still more preferably 25% by mass or less relative to the whole amount of the solid content in the colored resin composition.

Here, the term “the whole amount of the solid content” as used herein means the amount obtained by removing the content of the solvent from the whole amount of the colored resin composition. The whole amount of the solid content and the content of each component with respect thereto can be measured by known analysis means such as liquid chromatography or gas chromatography.

The content rate of the red pigment(s) is preferably 5% by mass or more, more preferably 10% by mass or more, still more preferably 15% by mass or more, and still more preferably 20% by mass or more, and is preferably 85% by mass or less, more preferably 80% by mass or less, still more preferably 75% by mass or less, still more preferably 70% by mass or less, more preferably 60% by mass or less, still more preferably 55% by mass or less, still more preferably 50% by mass or less, and still more preferably 45% by mass or less in the whole amount of the colorant (A).

The content rate of the red pigment(s) is preferably 5% by mass or more, more preferably 8% by mass or more, and still more preferably 10% by mass or more, and is preferably 45% by mass or less, more preferably 40% by mass or less, still more preferably 35% by mass or less, still more preferably 30% by mass or less, and more preferably 25% by mass or less relative to the whole amount of the solid content in the colored resin composition.

The content rate of the yellow pigment(s) is preferably 3% by mass or more, more preferably 5% by mass or more, still more preferably 10% by mass or more, still more preferably 13% by mass or more, still more preferably 15% by mass or more, still more preferably 20% by mass or more, and still more preferably 25% by mass or more, and is preferably 55% by mass or less, more preferably 50% by mass or less, still more preferably 45% by mass or less, and still more preferably 40% by mass or less in the whole amount of the colorant (A).

The content rate of the yellow pigment(s) is preferably 3% by mass or more, more preferably 5% by mass or more, still more preferably 6% by mass or more, still more preferably 8% by mass or more, and more preferably 10% by mass or more, and is preferably 30% by mass or less, more preferably 25% by mass or less, and still more preferably 20% by mass or less relative to the whole amount of the solid content in the colored resin composition.

The content of C.I. Pigment Violet 19 is preferably 10 parts by mass or more, more preferably 15 parts by mass or more, and still more preferably 20 parts by mass or more, and is preferably 150 parts by mass or less, more preferably 120 parts by mass or less, and still more preferably 100 parts by mass or less relative to the total 100 parts by mass of the red pigment(s) and the yellow pigment(s).

The content ratio of C.I. Pigment Violet 19 to the red pigment(s) (C.I. Pigment Violet 19/red pigment(s)) is preferably 0.2 or more, more preferably 0.25 or more, still more preferably 0.3 or more, and still more preferably 0.4 or more, and preferably 2.0 or less, more preferably 1.8 or less, and still more preferably 1.6 or less on the basis of mass.

The content ratio of C.I. Pigment Violet 19 to the yellow pigment(s) (C.I. Pigment Violet 19/yellow pigment(s)) is preferably 0.2 or more, more preferably 0.3 or more, still more preferably 0.4 or more, and is preferably 2.2 or less, more preferably 2.0 or less, and still more preferably 1.9 or less, still more preferably 1.8 or less, still more preferably 1.6 or less, and still more preferably 1.4 or less on the basis of mass.

The content ratio of the red pigment(s) to the yellow pigment(s) (red pigment(s)/yellow pigment(s)) is preferably 0.4 or more, more preferably 0.5 or more, and still more preferably 0.6 or more, and is preferably 6.0 or less, more preferably 5.0 or less, still more preferably 4.6 or less, still more preferably 1.7 or less, more preferably 1.5 or less, and still more preferably 1.3 or less on the basis of mass.

As the pigment(s) (A1), further a pigment (A1-1) other than C.I. Pigment Violet 19, the red pigment(s) and the yellow pigment(s) may be contained. The pigment (A1-1) is not particularly limited and a known pigment can be used, and examples thereof include pigments classified as pigments on the basis of the Color Index (The Society of Dyers and Colourists publication).

Examples of the pigment (A1-1) include: orange pigments such as C.I. Pigment oranges 13, 31, 36, 38, 40, 42, 43, 51, 55, 59, 61, 64, 65, 71, and 73;

blue pigments such as C.I. Pigment blues 15, 15:1, 15:2, 15:3, 15:4, 15:6, 16, and 60;
violet pigments other than C.I. Pigment Violet 19, such as C.I. Pigment Violets 1, 23, 32, 36, and 38; green pigments such as C.I. Pigment greens 7, 36, 58, 59, 62, and 63;
brown pigments such as C.I. Pigment browns 23 and 25; and
black pigments such as C.I. Pigment blacks 1 and 7.

When the pigment (A1-1) is contained, the content rate of the pigment (A1-1) is preferably 0.1% by mass or more, more preferably 0.5% by mass or more, and still more preferably 1% by mass or more, and is preferably 40% by mass or less, more preferably 30% by mass or less, and still more preferably 20% by mass or less in the whole amount of the colorant (A).

The content rate of the colorant (A) is preferably 10% by mass or more, more preferably 15% by mass or more, still more preferably 20% by mass or more, and still more preferably 25% by mass or more, and is preferably 70% by mass or less, more preferably 65% by mass or less, and still more preferably 60% by mass or less relative to the whole amount of the solid content in the colored resin composition. The content rate of the colorant (A) falling within the above-mentioned range is preferable, since the color density of the thus produced color filter is sufficient, the composition contains a necessary amount of the resin (B), and thus a pattern having sufficient mechanical strength can be formed.

The content ratio of the colorant (A) to the resin (B) described later (colorant (A)/resin (B)) is preferably 1.5 or more, more preferably 1.8 or more, and still more preferably 2.0 or more, and is preferably 4.0 or less, more preferably 3.5 or less, and still more preferably 3.2 or less on the basis of mass.

Further, the total content rate of C.I. Pigment Violet 19, the red pigment(s) and the yellow pigment(s) contained in the colorant (A) is preferably 80% by mass or more, more preferably 85% by mass or more, still more preferably 90% by mass or more, and may be 100% by mass in the whole amount of the colorant (A).

C.I. Pigment Violet 19, the red pigment(s), the yellow pigment(s) and the pigment (A1-1) may be subjected to a rosin treatment, a surface treatment using a derivative or the like having an introduced acidic group or basic group, a pigment surface graft treatment with a polymeric compound or the like, a particle micronization treatment with a sulfuric acid micronization method or the like, a washing treatment with an organic solvent, water or the like for removing impurities, a treatment for removing ionic impurities or the like by an ionic exchange method or the like, if required. Each of the pigments preferably has an approximately uniform particle diameter. A dispersant is added to the pigments for dispersion treatment, whereby a pigment dispersion in which the pigments are uniformly dispersed in a dispersant solution can be produced.

Examples of the dispersant include surfactants, and the dispersant may be, for example, any one of cationic, anionic, non-ionic, and amphoteric surfactants. Specific examples thereof include surfactants such as polyester-based, polyamine-based, and acrylic surfactants. These dispersants may be used singly or in combinations of two or more thereof. Examples of the dispersant represented by its trade name include KP (manufactured by Shin-Etsu Chemical Co., Ltd.), Flowlen (manufactured by Kyoeisha Chemical Co., Ltd.), Solsperse (registered trademark) (manufactured by Zeneca Ltd.), EFKA (registered trademark) (manufactured by BASF Corporation), AJISPER (registered trademark) (manufactured by Ajinomoto Fine-Techno Co., Inc.), Disperbyk (registered trademark) (manufactured by BYK-Chemie Corporation), and BYK (registered trademark) (manufactured by BYK-Chemie Corporation). The resin (B) described later may also be used as the dispersant.

When the dispersant is used, the amount of the dispersant (solid content) used is usually 10 to 200 parts by mass, preferably 13 to 180 parts by mass, and more preferably 15 to 160 parts by mass relative to 100 parts by mass of the pigment(S) (A1). When the amount of the dispersant used falls within the above-mentioned range, there is a tendency that a pigment dispersion having a uniform dispersion state is obtained.

### <Resin (B)>

The resin (B) is not particularly limited, and is preferably an alkali soluble resin. Examples of the resin (B) include the following resins [K1] to [K6].

Resin [K1]; a copolymer having a structural unit derived from at least one (a) selected from the group consisting of an unsaturated carboxylic acid and an unsaturated carboxylic anhydride (hereinafter, sometimes referred to as “(a)”) and a structural unit derived from a monomer (b) having a cyclic ether structure having 2 to 4 carbon atoms and an ethylenically unsaturated bond (hereinafter, sometimes referred to as “(b)”);

Resin [K2]; a copolymer having a structural unit derived from (a), a structural unit derived from (b), and a monomer (c) copolymerizable with (a) (provided that (c) is different from (a) and (b)) (hereinafter, sometimes referred to as “(c)”);

Resin [K3]; a copolymer having a structural unit derived from (a) and a structural unit derived from (c);

Resin [K4]; a copolymer having a structural unit produced by adding (b) to a structural unit derived from (a) and a structural unit derived from (c);

Resin [K5]; a copolymer having a structural unit produced by adding (a) to a structural unit derived from (b) and a structural unit derived from (c); and

Resin [K6]; a copolymer having a structural unit produced by adding (a) to a structural unit derived from (b) and further adding a polyvalent carboxylic acid and/or a carboxylic anhydride to the structural unit, and a structural unit derived from (c).

Specific examples of (a) include unsaturated monocarboxylic acids such as acrylic acid, methacrylic acid, crotonic acid, and o-, m- or p-vinylbenzoic acid;

unsaturated dicarboxylic acids such as maleic acid, fumaric acid, citraconic acid, mesaconic acid, itaconic acid, 3-vinylphthalic acid, 4-vinylphthalic acid, 3,4,5,6-tetrahydrophthalic acid, 1,2,3,6-tetrahydrophthalic acid, dimethyltetrahydrophthalic acid, and 1,4-cyclohexenedicarboxylic acid;

carboxy group-containing bicyclo unsaturated compounds such as methyl-5-norbornene-2,3-dicarboxylic acid, 5-carboxybicyclo[2.2.1]hept-2-ene, 5,6-dicarboxybicyclo[2.2.1]hept-2-ene, 5-carboxy-5-methylbicyclo[2.2.1]hept-2-ene, 5-carboxy-5-ethylbicyclo[2.2.1]hept-2-ene, 5-carboxy-6-methylbicyclo[2.2.1]hept-2-ene, and 5-carboxy-6-ethylbicyclo[2.2.1]hept-2-ene;

unsaturated dicarboxylic anhydrides such as maleic anhydride, citraconic anhydride, itaconic anhydride, 3-vinylphthalic anhydride, 4-vinylphthalic anhydride, 3,4,5,6-tetrahydrophthalic anhydride, 1,2,3,6-tetrahydrophthalic anhydride, dimethyltetrahydrophthalic anhydride, and 5,6-dicarboxybicyclo[2.2.1]hept-2-ene anhydride;

unsaturated mono[(meth)acryloyloxyalkyl]esters of a polyvalent carboxylic acid having a valence of 2 or more such as succinic acid mono[2-(meth)acryloyloxyethyl], and phthalic acid mono[2-(meth)acryloyloxyethyl]; and unsaturated acrylates containing a hydroxy group and a carboxy group in the same molecule such as α-(hydroxymethyl) acrylic acid.

Among these, from the viewpoint of copolymerization reactivity and solubility of a resin to be produced to an alkaline aqueous solution, acrylic acid, methacrylic acid and the like are preferable.

(b) means a polymerizable compound having, for example, a cyclic ether structure having 2 to 4 carbon atoms (for example, at least one selected from the group consisting of an oxirane ring, an oxetane ring, and a tetrahydrofuran ring) and an ethylenically unsaturated bond. (b) is preferably a monomer having a cyclic ether having 2 to 4 carbon atoms and a (meth)acryloyloxy group.

As used herein, “(meth)acrylic acid” represents at least one selected from the group consisting of acrylic acid and methacrylic acid. The terms “(meth)acryloyl”, “(meth)acrylate” and the like also have similar meanings.

Examples of (b) include a monomer having an oxiranyl group and an ethylenically unsaturated bond (b1) (hereinafter, sometimes referred to as “(b1)”), a monomer having an oxetanyl group and an ethylenically unsaturated bond (b2) (hereinafter, sometimes referred to as “(b2)”), and a monomer having a tetrahydrofuryl group and an ethylenically unsaturated bond (b3) (hereinafter, sometimes referred to as “(b3)”).

Examples of (b1) include a monomer having a structure where a linear or branched aliphatic unsaturated hydrocarbon is epoxidized (b1-1) (hereinafter, sometimes referred to as “(b1-1)”) and a monomer having a structure where an alicyclic unsaturated hydrocarbon is epoxidized (b1-2) (hereinafter, sometimes referred to as “b1-2”).

Examples of (b1-1) include glycidyl(meth)acrylate, β-methylglycidyl(meth)acrylate, β-ethylglycidyl(meth)acrylate, glycidyl vinyl ether, o-vinylbenzyl glycidyl ether, m-vinylbenzyl glycidyl ether, p-vinylbenzyl glycidyl ether, α-methyl-o-vinylbenzyl glycidyl ether, α-methyl-m-vinylbenzyl glycidyl ether, α-methyl-p-vinylbenzyl glycidyl ether, 2,3-bis(glycidyloxymethyl)styrene, 2,4-bis(glycidyloxymethyl)styrene, 2,5-bis(glycidyloxymethyl)styrene, 2,6-bis(glycidyloxymethyl)styrene, 2,3,4-tris(glycidyloxymethyl)styrene, 2,3,5-tris(glycidyloxymethyl)styrene, 2,3,6-tris(glycidyloxymethyl)styrene, 3,4,5-tris(glycidyloxymethyl)styrene, and 2,4,6-tris(glycidyloxymethyl)styrene.

Examples of (b1-2) include vinylcyclohexene monoxide, 1,2-epoxy-4-vinylcyclohexane (for example, CELLOXIDE 2000; manufactured by Daicel Corporation), 3,4-epoxycyclohexylmethyl(meth)acrylate (for example, Cyclomer A400; manufactured by Daicel Corporation), 3,4-epoxycyclohexylmethyl(meth)acrylate (for example, Cyclomer M100; manufactured by Daicel Corporation), 3,4-epoxytricyclo[5.2.1.0^{2,6}]decyl(meth)acrylate, and 3,4-epoxytricyclo[5.2.1.0^{2,6}]decyloxyethyl(meth)acrylate.

(b2) is more preferably a monomer having an oxetanyl group and a (meth)acryloyloxy group. Examples of (b2) include 3-methyl-3-methacryloyloxy methyl oxetane, 3-methyl-3-acryloyloxy methyl oxetane, 3-ethyl-3-methacryloyloxy methyl oxetane, 3-ethyl-3-acryloyloxy methyl oxetane, 3-methyl-3-methacryloyloxy ethyl oxetane, 3-methyl-3-acryloyloxy ethyl oxetane, 3-ethyl-3-methacryloyloxy ethyl oxetane, and 3-ethyl-3-acryloyloxy ethyl oxetane.

(b3) is more preferably a monomer having a tetrahydrofuryl group and a (meth)acryloyloxy group. Specific examples of (b3) include tetrahydrofurfuryl acrylate (for example, Viscoat V #150, manufactured by Osaka Organic Chemical Industry Ltd.) and tetrahydrofurfuryl methacrylate.

(b) is preferably (b1) since reliabilities such as heat resistance and chemical resistance of a color filter to be produced can be further improved.

Examples of (c) include (meth)acrylic esters such as methyl(meth)acrylate, ethyl(meth)acrylate, n-butyl(meth)acrylate, sec-butyl(meth)acrylate, tert-butyl(meth)acrylate, 2-ethylhexyl(meth)acrylate, dodecyl(meth)acrylate, lauryl(meth)acrylate, stearyl(meth)acrylate, cyclopentyl(meth)acrylate, cyclohexyl(meth)acrylate, 2-methylcyclohexyl(meth)acrylate, tricyclo[5.2.1.0^{2,6}]decan-8-yl(meth)acrylate (referred to as “dicyclopentanyl(meth)acrylate” (common name) in the art or sometimes referred to as “tricyclodecyl(meth)acrylate”), tricyclo[5.2.1.0^{2,6}]decene-8-yl(meth)acrylate (which is referred to as “dicyclopentenyl(meth)acrylate” (common name) in the art), dicyclopentanyloxyethyl(meth)acrylate, isobornyl(meth)acrylate, adamantyl(meth)acrylate, allyl(meth)acrylate, propargyl(meth)acrylate, phenyl(meth)acrylate, naphthyl(meth)acrylate, and benzyl(meth)acrylate;

hydroxy group-containing (meth)acrylic esters such as 2-hydroxyethyl(meth)acrylate and 2-hydroxypropyl(meth)acrylate;

dicarboxylic diesters such as diethyl maleate, diethyl fumarate, and diethyl itaconate;

bicyclo unsaturated compounds such as bicyclo[2.2.1]hept-2-ene, 5-methylbicyclo[2.2.1]hept-2-ene, 5-ethylbicyclo[2.2.1]hept-2-ene, 5-hydroxybicyclo[2.2.1]hept-2-ene, 5-hydroxymethylbicyclo[2.2.1]hept-2-ene, 5-(2′-hydroxyethyl)bicyclo[2.2.1]hept-2-ene, 5-methoxybicyclo[2.2.1]hept-2-ene, 5-ethoxybicyclo[2.2.1]hept-2-ene, 5,6-dihydroxybicyclo[2.2.1]hept-2-ene, 5,6-di(hydroxymethyl)bicyclo[2.2.1]hept-2-ene, 5,6-di(2′-hydroxyethyl)bicyclo[2.2.1]hept-2-ene, 5,6-dimethoxybicyclo[2.2.1]hept-2-ene, 5,6-diethoxybicyclo[2.2.1]hept-2-ene, 5-hydroxy-5-methylbicyclo[2.2.1]hept-2-ene, 5-hydroxy-5-ethylbicyclo[2.2.1]hept-2-ene, 5-hydroxymethyl-5-methylbicyclo[2.2.1]hept-2-ene, 5-tert-butoxycarbonylbicyclo[2.2.1]hept-2-ene, 5-cyclohexyloxycarbonylbicyclo[2.2.1]hept-2-ene, 5-phenoxycarbonylbicyclo[2.2.1]hept-2-ene, 5,6-bis(tert-butoxycarbonyl)bicyclo[2.2.1]hept-2-ene, and 5,6-bis(cyclohexyloxycarbonyl)bicyclo[2.2.1]hept-2-ene;

dicarbonylimide derivatives such as N-phenylmaleimide, N-cyclohexylmaleimide, N-benzylmaleimide, N-succinimidyl-3-maleimidobenzoate, N-succinimidyl-4-maleimidobutyrate, N-succinimidyl-6-maleimide caproate, N-succinimidyl-3-maleimide propionate, and N-(9-acridinyl)maleimide;

styrene, α-methylstyrene, m-methylstyrene, p-methylstyrene, vinyltoluene, p-methoxystyrene, acrylonitrile, methacrylonitrile, vinyl chloride, vinylidene chloride, acrylamide, methacrylamide, vinyl acetate, 1,3-butadiene, isoprene, and 2,3-dimethyl-1,3-butadiene.

Among these, (meth)acrylic esters are preferable.

In the resin [K1], the ratio of the structural unit derived from each of (a) and (b) in the total structural units constituting the resin [K1] is preferably the following:

the structural unit derived from (a); 2 to 60 mol %; and
the structural unit derived from (b); 40 to 98 mol %, and more preferably the following:
the structural unit derived from (a); 10 to 50 mol %; and
the structural unit derived from (b); 50 to 90 mol %.

When the ratio of the structural unit of the resin

[K1] falls within the above-mentioned range, there is a tendency that the storage stability of the colored resin composition, that the developability thereof during the formation of a colored pattern, and that the solvent resistance of a color filter to be produced are excellent.

The resin [K1] can be produced with reference to the method described in for example, a document “Experimental Method for Polymer Synthesis” (edited by Takayuki Otsu, published by Kagaku Dojin Publishing Co., Ltd., First Edition, First Printed on Mar. 1, 1972) and cited documents described in the above-mentioned document.

Specific examples thereof include the following method: predetermined amounts of (a) and (b), a polymerization initiator, a solvent and the like are placed in a reaction vessel; for example, a deoxidization atmosphere is formed by substituting oxygen with nitrogen; and these are heated or kept warm during stirring. The polymerization initiator, the solvent and the like which are used here are not particularly limited, and those commonly used in the art can be used. Examples of the polymerization initiator include azo compounds (2,2′-azobisisobutyronitrile, 2,2′-azobis(2,4-dimethylvaleronitrile) and the like) and organic peroxides (benzoyl peroxide, t-butylperoxy-2-ethylhexanoate and the like). The solvent may be a solvent capable of dissolving each monomer, and examples thereof include solvents to be described later, as the organic solvent (E) for the colored resin composition of the present invention.

A solution after a reaction, of the resultant copolymer may be used as it is; a concentrated or diluted solution of the copolymer may be used; or a solid (powder) taken out from the copolymer by a method such as reprecipitation may be used. In particular, the solution after the reaction can be used as it is for preparing the colored resin composition of the present invention by using the solvent contained in the colored resin composition of the present invention as the solvent during the polymerization, whereby the producing process of the colored resin composition of the present invention can be simplified.

In the resin [K2], the ratio of the structural unit derived from each of (a) to (c) in the total structural units constituting the resin [K2] is preferably the following:

the structural unit derived from (a); 2 to 45 mol %;
the structural unit derived from (b); 2 to 95 mol %; and
the structural unit derived from (c); 1 to 65 mol %, and more preferably the following:
the structural unit derived from (a); 5 to 40 mol %;
the structural unit derived from (b); 5 to 80 mol %; and
the structural unit derived from (c); 5 to 60 mol %.

When the ratio of the structural unit of the resin [K2] falls within the above-mentioned range, there is a tendency that the storage stability of the colored resin composition, the developability thereof during the formation of a colored pattern, and the solvent resistance, heat resistance, and mechanical strength of a color filter to be produced are excellent.

The resin [K2] can be produced in the same manner as in the method described as the producing method of the resin [K1], for example.

In the resin [K3], the ratio of the structural unit derived from each of (a) and (c) in the total structural units constituting the resin [K3] is preferably the following:

the structural unit derived from (a); 2 to 60 mol %; and
the structural unit derived from (c); 40 to 98 mol %, and more preferably the following:
the structural unit derived from (a); 10 to 50 mol % and
the structural unit derived from (c); 50 to 90 mol %.

The resin [K3] can be produced in the same manner as in the method described as the producing method of the resin [K1], for example.

The resin [K4] can be produced by producing a copolymer of (a) and (c) and then adding a cyclic ether having 2 to 4 carbon atoms contained in (b) to a carboxylic acid and/or a carboxylic anhydride contained in (a).

The copolymer of (a) and (c) is first produced in the same manner as in the method described as the producing method of the resin [K1]. In this case, the ratio of the structural unit derived from each of (a) and (c) is preferably the same ratio as that described in the resin [K3].

Next, a cyclic ether having 2 to 4 carbon atoms contained in (b) is reacted with a part of the carboxylic acid and/or the carboxylic anhydride derived from (a) in the copolymer.

Subsequent to the production of the copolymer of (a) and (c), a nitrogen atmosphere in a flask is replaced with air, and (b), a reaction catalyst for a carboxylic acid or a carboxylic anhydride and a cyclic ether (for example, tris(dimethylaminomethyl)phenol, triphenylphosphine and the like), and a polymerization inhibitor (for example, hydroquinone, methoquinone and the like) are placed in a flask, followed by reacting, for example, at 60 to 130° C. for 1 to 10 hours, whereby the resin [K4] can be produced.

The amount of (b) used is preferably 5 to 80 mol, and more preferably 10 to 75 mol, relative to 100 mol of (a). The amount of (b) used falls within the above-mentioned range, whereby there is a tendency that the storage stability of the colored resin composition, the developability thereof during the formation of a pattern, and the balance of the solvent resistance, heat resistance, mechanical strength, and sensitivity of the pattern obtained are good. Since the reactivity of the cyclic ether is high, and the unreacted (b) is less likely to remain, (b) used for the resin [K4] is preferably (b1), and more preferably (b1-1).

The amount of the reaction catalyst used is preferably 0.001 to 5 parts by mass relative to 100 parts by mass of the total amount of (a), (b), and (c). The amount of the polymerization inhibitor used is preferably 0.001 to 5 parts by mass relative to 100 parts by mass of the total amount of (a), (b), and (c).

Reaction conditions such as a feeding method, a reaction temperature, and time can be appropriately adjusted in consideration of a production equipment, an amount of heat generation due to polymerization, and the like. In consideration of the production equipment, the amount of heat generation due to polymerization, and the like, the feeding method and the reaction temperature can be appropriately adjusted like the polymerization conditions.

The resin [K5] is produced by producing a copolymer of (b) and (c) in the same manner as in the above-mentioned method for producing the resin [K1] as a first step. In the same manner as in the above, a solution after a reaction, of the resultant copolymer may be used as it is; a concentrated or diluted solution of the copolymer may be used; or a solid (powder) taken out from the copolymer by a method such as reprecipitation may be used.

The ratio of the structural unit derived from each of (b) and (c) relative to the total number of moles of the total structural units constituting the copolymer is preferably the following:

the structural unit derived from (b); 5 to 95 mol %; and

the structural unit derived from (c); 5 to 95 mol %, and more preferably the following:

the structural unit derived from (b); 10 to 90 mol %; and

the structural unit derived from (c); 10 to 90 mol %.

Furthermore, the resin [K5] can be produced by reacting a carboxylic acid or a carboxylic anhydride contained in (a) with the cyclic ether derived from (b) contained in the copolymer of (b) and (c) under the same conditions as those of the producing method of the resin [K4].

The amount of (a) used which is reacted with the copolymer is preferably 5 to 100 mol relative to 100 mol of (b). Since the reactivity of the cyclic ether is high, and the unreacted (b) is less likely to remain, (b) used for the resin [K5] is preferably (b1), and more preferably (b1-1).

The resin [K6] is a resin produced by further reacting a polyvalent carboxylic acid and/or a carboxylic anhydride with the resin [K5]. A polyvalent carboxylic acid and/or a carboxylic anhydride is further reacted with a hydroxy group generated by a reaction of a cyclic ether derived from (b) with a carboxylic acid or a carboxylic anhydride derived from (a).

Examples of the polyvalent carboxylic acid include oxalic acid, malonic acid, succinic acid, maleic acid, fumaric acid, glutaric acid, and tricarbanyl acid. Examples of the carboxylic anhydride include a succinic anhydride, a maleic anhydride, a citraconic anhydride, an itaconic anhydride, a 3-vinylphthalic anhydride, a 4-vinylphthalic anhydride, a 3,4,5,6-tetrahydrophthalic anhydride, a 1,2,3,6-tetrahydrophthalic anhydride, a dimethyltetrahydrophthalic anhydride, and a 5,6-dicarboxybicyclo[2.2.1]hept-2-ene anhydride. The amount of the polyvalent carboxylic acid and/or the carboxylic anhydride used is preferably 0.05 to 1 mol and more preferably 0.1 to 0.5 mol relative to 1 mol of the amount of (a) used.

The resin (B) is preferably a resin (resin [K4], resin [K5], or resin [K6]) having a structural unit having an ethylenically unsaturated bond at its side chain, and is more preferably a resin having a structural unit containing a (meth)acryloyl group at its side chain.

Examples of the resin having a structural unit containing a (meth)acryloyl group at its side chain include the resin [K4] produced using a monomer having a (meth)acryloyl group such as a glycidyl(meth)acrylate, 3,4-epoxycyclohexylmethyl(meth)acrylate, 3-methyl-3-methacryloyloxy methyl oxetane, or tetrahydrofurfuryl acrylate as (b), the resin [K5] produced using a monomer having a (meth)acryloyl group such as acrylic acid, methacrylic acid, or mono[2-(meth)acryloyloxyethyl] succinate as (a), or the resin [K6] produced using a monomer having a (meth)acryloyl group such as acrylic acid, methacrylic acid, or mono[2-(meth)acryloyloxyethyl] succinate as (a). Such a resin having a structural unit containing a (meth)acryloyl group at its side chain is preferably the resin [K6] produced using a monomer having a (meth)acryloyl group such as acrylic acid, methacrylic acid, or mono[2-(meth)acryloyloxyethyl] succinate as (a).

The weight average molecular weight of the resin (B) in terms of polystyrene content is preferably 3,000 to 100,000, more preferably 4,000 to 50,000, and still more preferably 5,000 to 30,000. When the molecular weight falls within the above-mentioned range, there is a tendency that the hardness of the color filter is improved, that the residual film ratio is increased, that the solubility of an unexposed area in a developing solution becomes good, and that the resolution of a colored pattern is improved.

The degree of dispersion [weight average molecular weight (Mw)/number average molecular weight (Mn)] of the resin (B) is preferably 1.1 to 6, and more preferably 1.2 to 4.

The acid value of the resin (B) is preferably 10 to 170 mg-KOH/g, more preferably 20 to 150 mg-KOH/g, and still more preferably 30 to 135 mg-KOH/g, in terms of solid content. The acid value as used herein is a value which is measured as an amount (mg) of potassium hydroxide required for neutralizing 1 g of the resin (B), and which can be determined by, for example, titration with an aqueous potassium hydroxide solution.

The content rate of the resin (B) is preferably 5 to 50% by mass, more preferably 8 to 40% by mass, and still more preferably 10 to 35% by mass relative to the whole amount of the solid content in the colored resin composition. When the content rate of the resin (B) falls within the above-mentioned range, there is a tendency that the colored pattern can be formed, and that the resolution of the colored pattern and the residual film ratio are improved.

### <Polymerizable Compound (C)>

The polymerizable compound (C) is a compound capable of being polymerized by the action of an active radical and/or an acid generated from the polymerization initiator (D). Examples of the polymerizable compound (C) include a compound having a polymerizable ethylenically unsaturated bond, and is preferably a (meth)acrylic acid ester compound.

Among these, the polymerizable compound (C) is preferably a polymerizable compound having three or more ethylenically unsaturated bonds. Examples of the polymerizable compound include trimethylolpropane tri(meth)acrylate, pentaerythritol tri(meth)acrylate, pentaerythritol tetra(meth)acrylate, dipentaerythritol penta(meth)acrylate, and dipentaerythritol hexa(meth)acrylate.

The weight average molecular weight of the polymerizable compound (C) is preferably 150 or more and 2,900 or less, and more preferably 250 or more and 1,500 or less.

The content rate of the polymerizable compound (C) is preferably 3 to 30% by mass, more preferably 5 to 25% by mass, and still more preferably 8 to 20% by mass relative to the whole amount of the solid content in the colored resin composition.

### <Polymerization Initiator (D)>

The polymerization initiator (D) is not particularly limited, as long as the polymerization initiator (D) is a compound capable of generating active radicals, an acid or the like by the action of light or heat to initiate polymerization. Any known polymerization initiator can be used.

Examples of the polymerization initiator (D) include an O-acyloxime compound, an alkylphenone compound, a biimidazole compound, a triazine compound, and an acylphosphine oxide compound. A preferable example of the polymerization initiator (D) is an O-acyloxime compound.

The O-acyloxime compound is a compound having a structure represented by formula (d). Hereinafter, * represents a point of attachment.

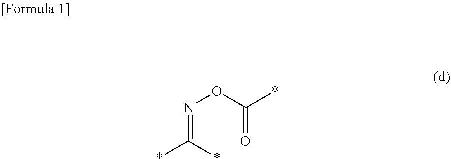 [SMILES: *C(=O)ON=C(*)*]

The O-acyloxime compound is, for example, preferably at least one type selected from the group consisting of a compound represented by the following formula (d1) (hereinafter, sometimes referred to as a compound (d1)), a compound represented by the following formula (d2) (hereinafter, sometimes referred to as a compound (d2)), and a compound represented by the following formula (d3) (hereinafter, sometimes referred to as a compound (d3)).

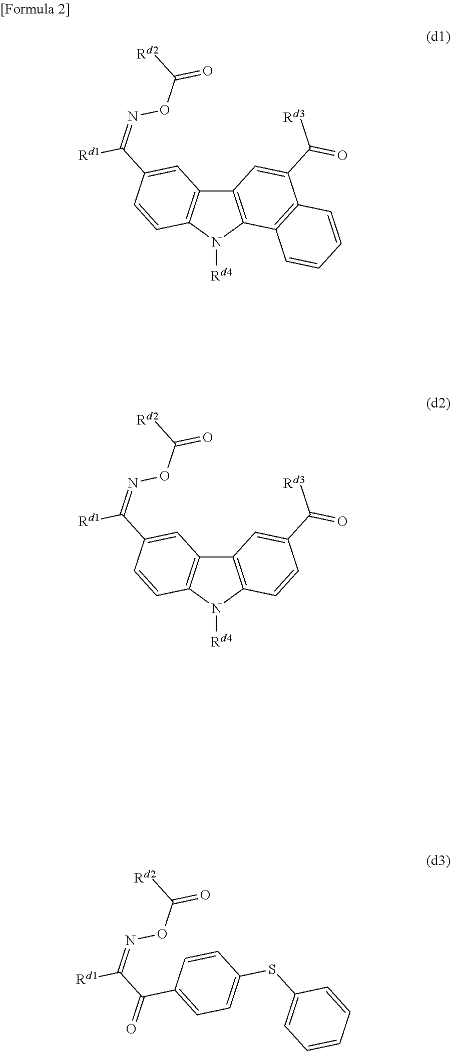

[In formulas (d1) to (d3),

R^{d1} represents an aromatic hydrocarbon group having 6 to 18 carbon atoms and optionally having a substituent, a heterocyclic group having 3 to 36 carbon atoms and optionally having a substituent, an alkyl group having 1 to 15 carbon atoms and optionally having a substituent, or a group being a combination of an aromatic hydrocarbon group and an alkanediyl group derived from the alkyl group and optionally having a substituent, and a methylene group (—CH₂—) contained in the alkyl group is optionally replaced with —O—, —CO—, —S—, —SO₂— or —NR^{d5}—.

R^{d2} represents an aromatic hydrocarbon group having 6 to 18 carbon atoms, a heterocyclic group having 3 to 36 carbon atoms or an alkyl group having 1 to 10 carbon atoms.

R^{d3} represents an aromatic hydrocarbon group having 6 to 18 carbon atoms and optionally having a substituent or a heterocyclic group having 3 to 36 carbon atoms and optionally having a substituent.

R^{d4} represents an aromatic hydrocarbon group having 6 to 18 carbon atoms and optionally having a substituent or an aliphatic hydrocarbon group having 1 to 15 carbon atoms and optionally having a substituent, wherein a methylene group (—CH₂—) contained in the aliphatic hydrocarbon group is optionally replaced with —O—, —CO— or —S—, a methine group (—CH—) contained in the aliphatic hydrocarbon group is optionally replaced with —PO₃<, and a hydrogen atom contained in the aliphatic hydrocarbon group is optionally replaced with an OH group.

R^{d5} represents an alkyl group having 1 to 10 carbon atoms, wherein a methylene group (—CH₂—) contained in the alkyl group is optionally replaced with —O— or —CO—.]

The number of carbon atoms of the aromatic hydrocarbon group represented by R^{d1} is preferably 6 to 15, more preferably 6 to 12, and still more preferably 6 to 10. Examples of the aromatic hydrocarbon group include a phenyl group, a naphthyl group, an anthryl group, a phenanthryl group, a biphenyl group, and a terphenyl group. A phenyl group and a naphthyl group are more preferable and a phenyl group is particularly preferable.

The aromatic hydrocarbon group represented by R^{d1} may have 1 or 2 or more substituents. A substituent is preferably at position a or γ of the aromatic hydrocarbon group, and is more preferably at position γ as a result of replacement. Examples of the substituent include: an alkyl group having 1 to 15 carbon atoms such as a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group and a pentadecyl group; and a halogen atom such as a fluorine atom, a chlorine atom, an iodine atom, and a bromine atom.

The number of carbon atoms of an alkyl group as the substituent is preferably 1 to 10, and more preferably 1 to 7. Alkyl groups as the substituents may be either linear, branched, or cyclic, or may be combined groups of chain groups and cyclic groups. A methylene group (—CH₂—) contained in an alkyl group as the substituent is optionally replaced with —O— or —S—. Further, a hydrogen atom contained in the alkyl group is optionally replaced with a halogen atom such as a fluorine atom, a chlorine atom, an iodine atom, and a bromine atom, and may be preferably replaced with a fluorine atom.

Examples of an alkyl group as a substituent of the aromatic hydrocarbon group represented by R^{d1} include groups represented by the following formulas. In the formulas, * represents a point of attachment.

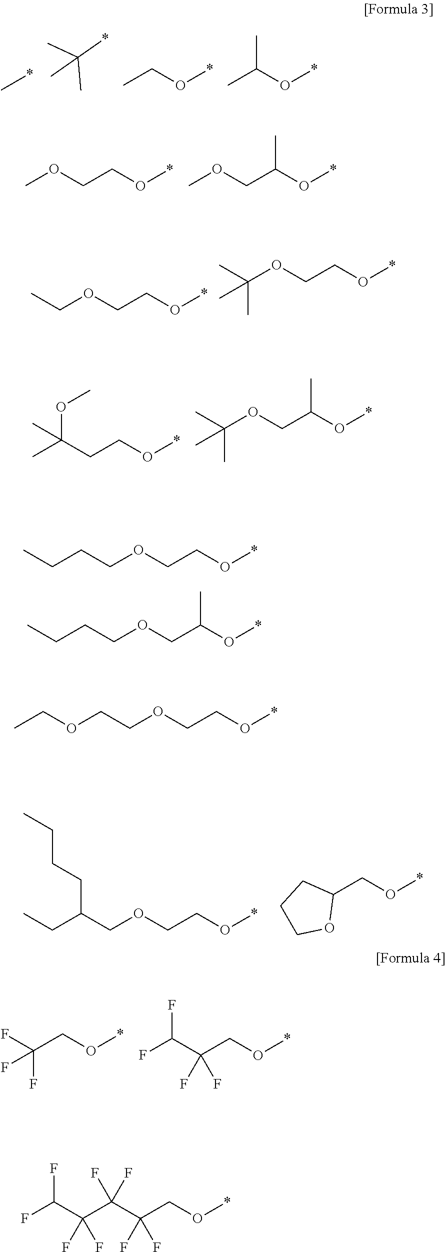

Examples of the aromatic hydrocarbon group represented by R^{d1} and optionally having a substituent include groups represented by the following formulas. In the formulas, * represents a point of attachment.

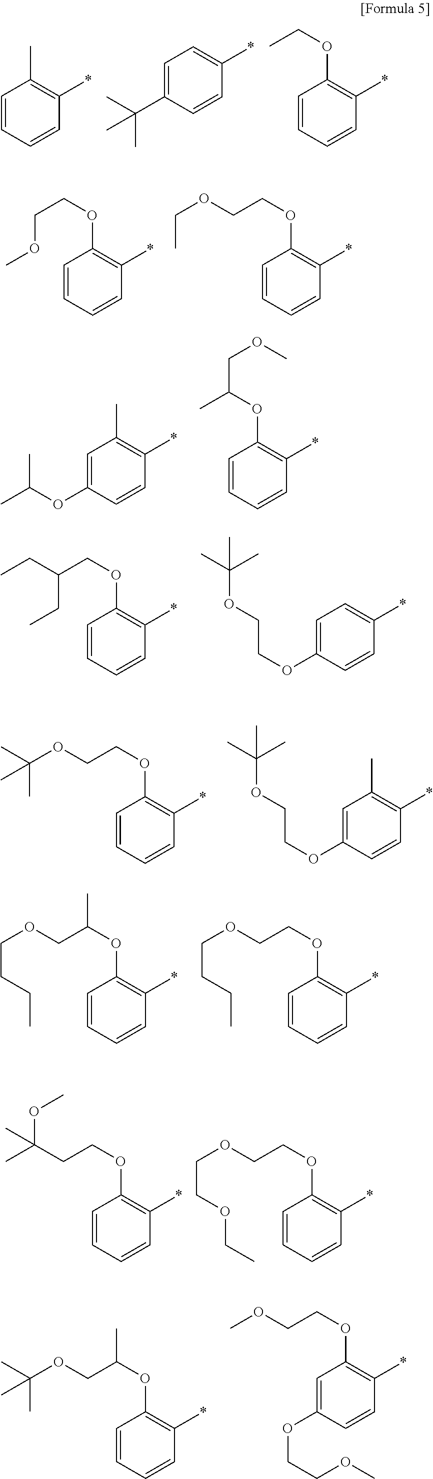

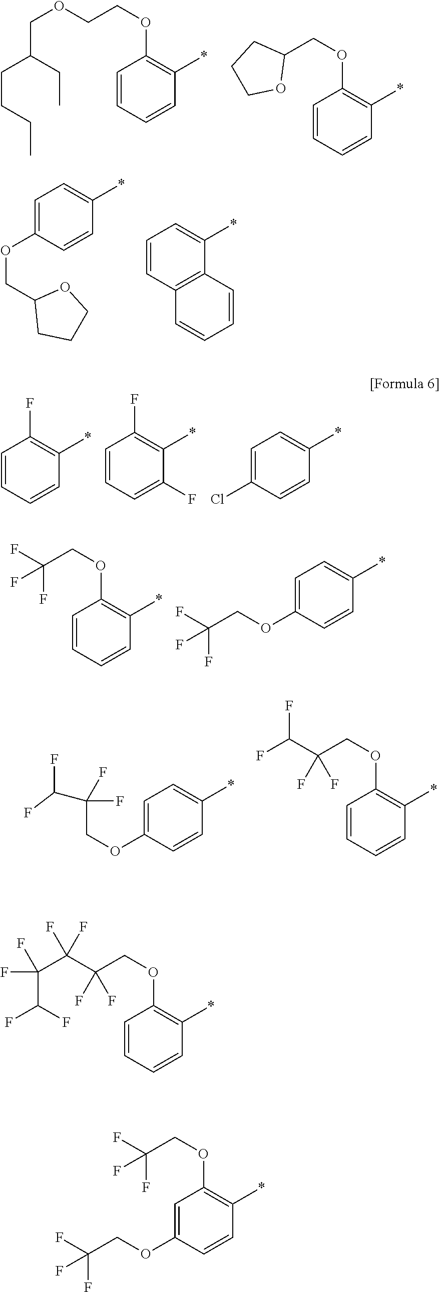

The aromatic hydrocarbon group represented by R^{d1} and optionally having a substituent is preferably a group represented by the following formula.

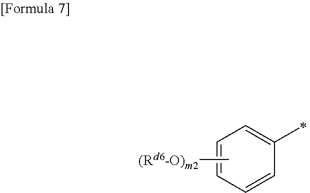

[In the formula, R^{d6} represents an alkyl group having 1 to 10 carbon atoms, which is optionally replaced with a halogen atom, a hydrogen atom contained in R^{d6} may be replaced with a halogen atom, and m2 represents an integer of 1 to 5.]

Examples of the alkyl group represented by R^{d6} include groups similar to alkyl groups exemplified as the substituent of the aromatic hydrocarbon group represented by R^{d1}. The number of carbon atoms of R^{d6} is preferably 2 to 7, and more preferably 2 to 5. Further, the alkyl group represented by R^{d6} may be either linear, branched, or cyclic, and is preferably a chain group.

Examples of a halogen atom that is optionally replaced with a hydrogen atom contained in R^{d6} include a fluorine atom, a chlorine atom, an iodine atom, and a bromine atom, and a fluorine atom is particularly preferable. Further, 2 or more and 10 or less hydrogen atoms contained in R^{d6} are preferably replaced with halogen atoms, and 3 or more and 6 or less hydrogen atoms are preferably replaced with halogen atoms. The replacement position for O— group in R^{d6} is preferably at the ortho position or the para position, and the para position is particularly preferable.

Further, m2 is preferably 1 to 2, and particularly preferably 1.

The number of carbon atoms of the heterocyclic group represented by R^{d1} is preferably 3 to 20, more preferably 3 to 10, and still more preferably 3 to 5. Examples of the heterocyclic group include a pyrrolyl group, a furyl group, a thienyl group, an indolyl group, a benzofuryl group, and a carbazolyl group.

Further the heterocyclic group represented by R^{d1} may have 1 or 2 or more substituents. Examples of the substituent include groups similar to those exemplified as substituents that the aromatic hydrocarbon group represented by R^{d1} may have.

The number of carbon atoms of the alkyl group represented by R^{d1} is preferably 1 to 12. Examples of the alkyl group represented by R^{d1} include a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group and a pentadecyl group. These alkyl groups may be either linear, branched, or cyclic, or may be combined groups of chain groups and cyclic groups. Further, in the alkyl group represented by R^{d1}, a methylene group (—CH₂—) is optionally replaced with —O—, —CO—, —S—, —SO₂— or —NR^{d5}—, and a hydrogen atom is optionally replaced with an OH group or an SH group.

R^{d5} represents an alkyl group having 1 to 10 carbon atoms, and is preferably an alkyl group having 1 to 5 carbon atoms, and more preferably an alkyl group having 1 to 3 carbon atoms. The alkyl group may be either chain (linear or branched) or cyclic, may be either linear, branched or cyclic, and may be a combined group of a chain group and a cyclic group. Further, in the alkyl group represented by R^{d5}, a methylene group (—CH₂—) is optionally replaced with —O— or —CO—.

Specific examples of the alkyl group represented by R^{d1} and optionally having a substituent include groups represented by the following formula. * represents a point of attachment.

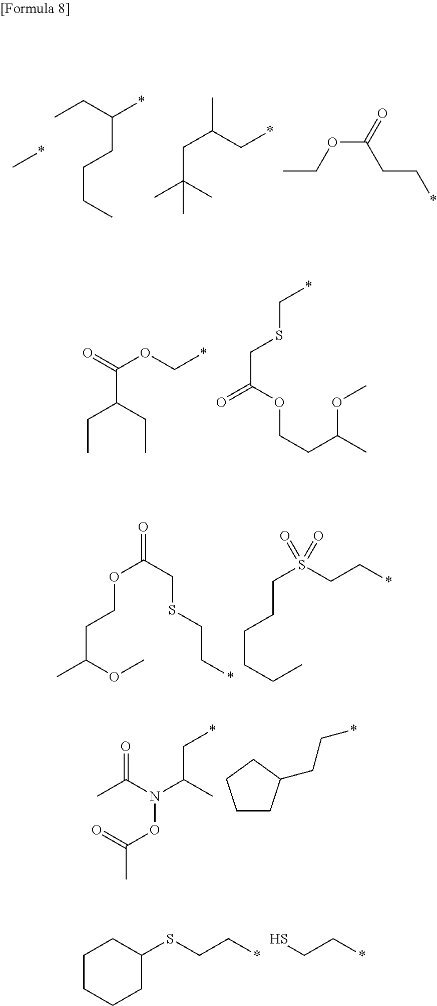

Furthermore, the number of carbon atoms of a combined group, which is represented by R^{d1} and is formed of an aromatic hydrocarbon group and an alkanediyl group derived from the alkyl group represented by R^{d1} above, is preferably 7 to 33, more preferably 7 to 18, and still more preferably 7 to 12. The combined group may have 1 or 2 or more substituents, and examples of the substituent include groups similar to those exemplified as the substituent that the aromatic hydrocarbon group and the alkyl group may have. Examples of a combined group, which is represented by Rd′ and is formed of the aromatic hydrocarbon group and an alkanediyl group derived from the alkyl group represented by R^{d1}, include an aralkyl group and a specific example thereof include a group represented by the following formula. In the formula, * represents a point of attachment.

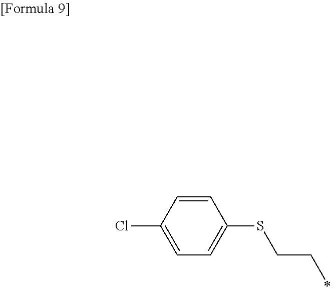

Among these, R^{d1} is preferably an aromatic hydrocarbon group optionally having a substituent or an alkyl group optionally having a substituent, and is more preferably an aromatic hydrocarbon group optionally having a substituent.

The number of carbon atoms of the aromatic hydrocarbon group represented by R^{d2} is preferably 6 to 15, more preferably 6 to 12, and still more preferably 6 to 10. Examples of the aromatic hydrocarbon group include a phenyl group, a naphthyl group, an anthryl group, a phenanthryl group, a biphenyl group, and a terphenyl group.

The number of carbon atoms of the heterocyclic group represented by R^{d2} is preferably 3 to 20, more preferably 3 to 10, and still more preferably 3 to 5. Examples of the heterocyclic group include a pyrrolyl group, a furyl group, a thienyl group, an indolyl group, a benzofuryl group, and a carbazolyl group.

The number of carbon atoms of the alkyl group represented by R^{d2} is preferably 1 to 7, more preferably 1 to 5, and still more preferably 1 to 3. Examples of the alkyl group include a methyl group, an ethyl group, a propyl group, a butyl group, a pentyl group, a hexyl group, a heptyl group, an octyl group, a nonyl group and a decyl group. The alkyl group may be either linear, branched, or cyclic, or a combined group of a chain group and a cyclic group.

R^{d2} is preferably a chain alkyl group, more preferably a chain alkyl group having 1 to 5 carbon atoms, still more preferably a chain alkyl group having 1 to 3 carbon atoms and is particularly preferably a methyl group.

The number of carbon atoms of the aromatic hydrocarbon group represented by R^{d3} is preferably 6 to 15, more preferably 6 to 12, and still more preferably 6 to 10. Examples of the aromatic hydrocarbon group include a phenyl group, a naphthyl group, an anthryl group, a phenanthryl group, a biphenyl group, and a terphenyl group, and a phenyl group and a naphthyl group are more preferable.

Further, the aromatic hydrocarbon group represented by R^{d3} may have 1 or 2 or more substituents. The substituent(s) is preferably at position a or γ of the aromatic hydrocarbon group as a result of replacement. The substituent is preferably an aliphatic hydrocarbon group having 1 to 15 carbon atoms and specific examples thereof include: an alkyl group having 1 to 15 carbon atoms such as a methyl group, an ethyl group, a propyl group, a butyl group, a pentyl group, a hexyl group, a heptyl group, an octyl group, a nonyl group and a decyl group; and an alkenyl group having 1 to 15 carbon atoms such as an ethenyl group, propenyl group, a butenyl group, a pentenyl group, a hexenyl group, a heptenyl group, a nonenyl group and a decenyl group.

The number of carbon atoms of the aliphatic hydrocarbon group that the aromatic hydrocarbon group represented by R^{d3} may have is more preferably 1 to 7. The aliphatic hydrocarbon group may be either linear, branched, or cyclic, or a combined group of a chain group and a cyclic group. Further, a methylene group (—CH₂—) contained in the aliphatic hydrocarbon group is optionally replaced with —O—, —CO— or —S—, and a methine group (—CH—) is optionally replaced with —N<.

Examples of an aliphatic hydrocarbon group that the aliphatic hydrocarbon group represented by R^{d3} may have include groups represented by the following formula. In the formula, * represents a point of attachment.

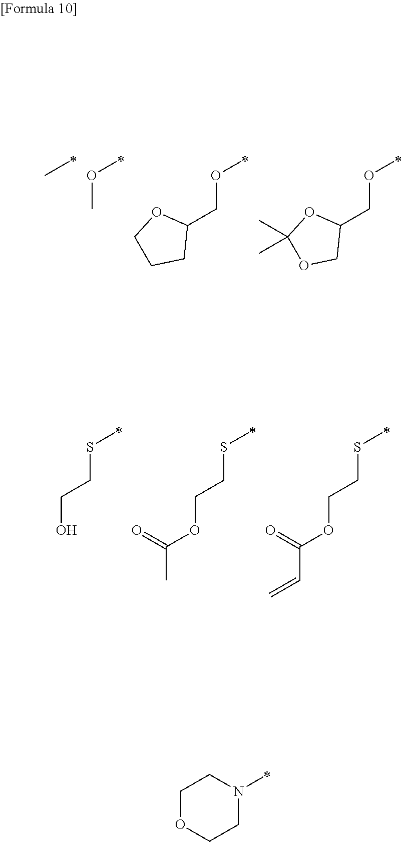

Examples of the aromatic hydrocarbon group represented by R^{d3} and optionally having a substituent include groups represented by the following formula. In the formula, * represents a point of attachment.

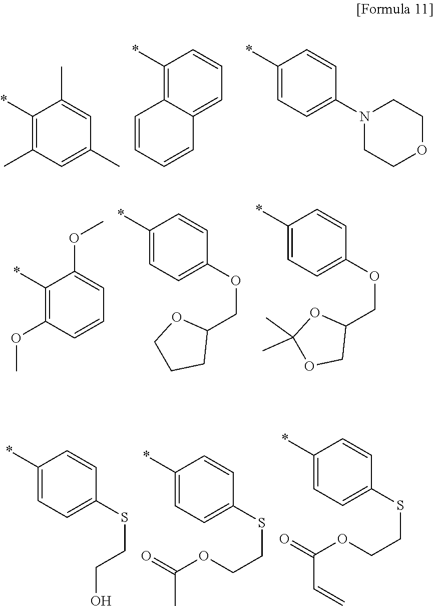

The number of carbon atoms of the heterocyclic group represented by R^{d3} is preferably 3 to 20, more preferably 3 to 10, and still more preferably 3 to 5. Examples of the heterocyclic group include a pyrrolyl group, a furyl group, a thienyl group, an indolyl group, a benzofuryl group, and a carbazolyl group.

Further, the heterocyclic group represented by R^{d3} may have 1 or 2 or more substituents, and examples of the substituents include groups similar to those exemplified as substituents that the aromatic hydrocarbon group represented by R^{d1} may have.

Among these, R^{d3} is preferably an aromatic hydrocarbon group having substituents, and the substituents are each preferably a chain alkyl group having 1 to 7 carbon atoms (more preferably 1 to 3 carbon atoms), and the number of substituents is preferably 2 or more and 5 or less.

The number of carbon atoms of the aromatic hydrocarbon group represented by R^{d4} is preferably 6 to 15, more preferably 6 to 12, and still more preferably 6 to 10. Examples of the aromatic hydrocarbon group include a phenyl group, a naphthyl group, an anthryl group, a phenanthryl group, a biphenyl group, and a terphenyl group, a phenyl group and a naphthyl group are more preferable and a phenyl group is still more preferable.

Further, the aromatic hydrocarbon group represented by R^{d4} may have 1 or 2 or more substituents. Examples of the substituents include groups similar to the substituents that the aromatic hydrocarbon group represented by R^{d1} may have.

The number of carbon atoms of the aliphatic hydrocarbon group represented by R^{d4} is preferably 1 to 13, more preferably 2 to 10, and still more preferably 4 to 9. Examples of the aliphatic hydrocarbon group represented by R^{d4} include: alkyl groups such as a methyl group, an ethyl group, a propyl group, a butyl group, a pentyl group, a hexyl group, a heptyl group, an octyl group, a nonyl group, a decyl group, an undecyl group, a dodecyl group, a tridecyl group, a tetradecyl group and a pentadecyl group; and alkenyl groups such as an ethenyl group, propenyl group, a butenyl group, a pentenyl group, a hexenyl group, a heptenyl group, an octenyl group, a nonenyl group, a decenyl group, an undecenyl group, a dodecenyl group, a tridecenyl group, a butadecenyl group and a pentadecenyl group. These aliphatic hydrocarbon groups may be either chain (linear or branched) or cyclic, and combined groups of chain groups and cyclic groups. Further, in the aliphatic hydrocarbon group represented by R^{d4}, a methylene group (—CH₂—) is optionally replaced with —O—, —CO— or —S—, a methine group (—CH—) is optionally replaced with —PO₃<, and a hydrogen atom contained in the aliphatic hydrocarbon group is optionally replaced with an OH group.

Examples of the aliphatic hydrocarbon group represented by R^{d4} and optionally having the substituent include groups represented by the following formula. In the formula, * represents a point of attachment.

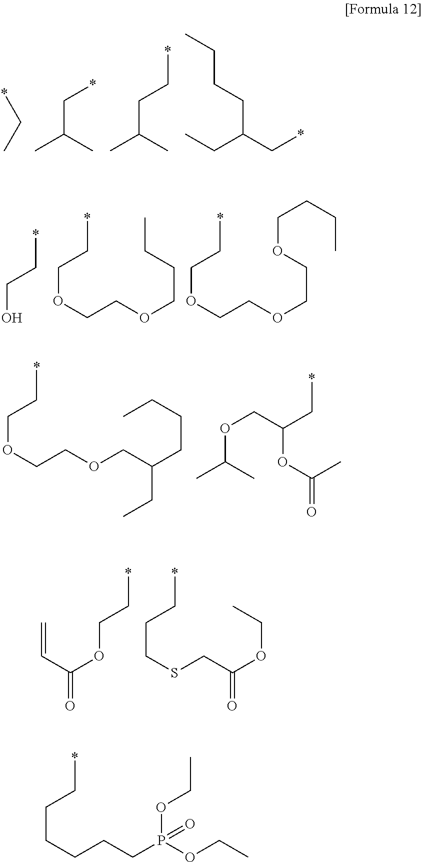

R^{d4} is preferably a chain aliphatic hydrocarbon group optionally having a substituent, more preferably a chain alkyl group having no substituent, and still more preferably a branched alkyl group having no substituent.

The compound (d1) can be produced by the production method disclosed in Japanese Translation of PCT International Application Publication No. 2014-500852.

The compound (d2) is preferably a compound wherein R^{d1} is an alkyl group having 1 to 15 carbon atoms and optionally having a substituent, R^{d2} is an alkyl group having 1 to 10 carbon atoms, R^{d3} is an aromatic hydrocarbon group having 6 to 18 carbon atoms and optionally having a substituent, R^{d4} is an aliphatic hydrocarbon group having 1 to 15 carbon atoms and optionally having a substituent,

is more preferably a compound wherein Rd′ represents a methyl group, an ethyl group or a propyl group, R^{d2} represents a methyl group, an ethyl group or a propyl group, R^{d3} represents a phenyl group replaced with a methyl group, and R^{d4} is a methyl group, an ethyl group or a propyl group,

is still more preferably a compound wherein R^{d1} and R^{d2} are methyl groups, R^{d3} is an o-tolyl group, and R^{d4} is an ethyl group.

The compound (d3) is preferably a compound wherein R^{d1} is an alkyl group having 1 to 15 carbon atoms and optionally having a substituent and R^{d2} is an aromatic hydrocarbon group having 6 to 18 carbon atoms, and is more preferably a compound wherein R^{d1} is a hexyl group and R^{d2} is a phenyl group.

Examples of the O-acyloxime compound include N-benzoyloxy-1-(4-phenylsulfanylphenyl)butane-1-one-2-imine, N-benzoyloxy-1-(4-phenylsulfanylphenyl)octane-1-one-2-imine, N-benzoyloxy-1-(4-phenylsulfanylphenyl)-3-cyclopentylpropane-1-one-2-imine, N-acetoxy-1-[9-ethyl-6-(2-methylbenzoyl)-9H-carbazole-3-yl]ethane-1-imine, N-acetoxy-1-[9-ethyl-6-{2-methyl-4-(3,3-dimethyl-2,4-dioxacyclopentanylmethyloxy)benzoyl}-9H-carbazole-3-yl]ethane-1-imine, N-acetoxy-1-[9-ethyl-6-(2-methylbenzoyl)-9H-carbazole-3-yl]-3-cyclopentylpropane-1-imine, and N-benzoyloxy-1-[9-ethyl-6-(2-methylbenzoyl)-9H-carbazole-3-yl]-3-cyclopentylpropane-1-one-2-imine. Commercially available products such as Irgacures OXE01, OXE02 and OXE03 (all manufactured by BASF Corporation), and N-1919 (manufactured by ADEKA Corporation) may be used.

The alkylphenone compound is a compound having a partial structure represented by formula (d4) or a partial structure represented by formula (d5). In these partial structures, the benzene ring optionally has a substituent.

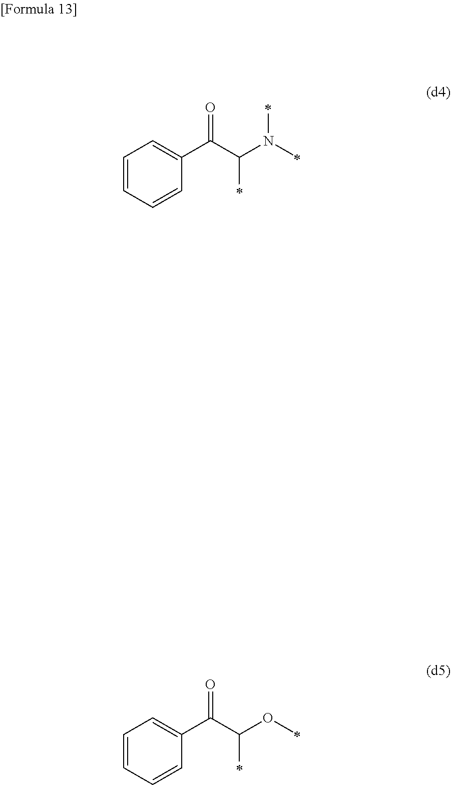

Examples of the compound having a structure represented by formula (d4) include 2-methyl-2-morpholino-1-(4-methylsulfanylphenyl)propane-1-one, 2-dimethylamino-1-(4-morpholinophenyl)-2-benzylbutane-1-one, and 2-(dimethylamino)-2-[(4-methylphenyl)methyl]-1-[4-(4-morpholinyl)phenyl]butane-1-one. Commercially available products such as Irgacures 369, 907, and 379 (all manufactured by BASF Corporation) may be used.

Examples of the compound having a structure represented by formula (d5) include 2-hydroxy-2-methyl-1-phenylpropane-1-one, 2-hydroxy-2-methyl-1-[4-(2-hydroxyethoxy)phenyl]propane-1-one, 1-hydroxycyclohexylphenylketone, an oligomer of 2-hydroxy-2-methyl-1-(4-isopropenylphenyl)propane-1-one, α,α-diethoxyacetophenone, and benzyl dimethyl ketal.

The alkylphenone compound is preferably a compound having a structure represented by formula (d4) from the viewpoint of sensitivity.

Examples of the biimidazole compound include 2,2′-bis(2-chlorophenyl)-4,4′,5,5′-tetraphenylbiimidazole, 2,2′-bis(2,3-dichlorophenyl)-4,4′,5,5′-tetraphenylbiimidazole (for example, see Japanese Patent Laid-Open No. 6-75372 and Japanese Patent Laid-Open No. 6-75373), 2,2′-bis(2-chlorophenyl)-4,4′,5,5′-tetra(alkoxyphenyl)biimidazole, 2,2′-bis(2-chlorophenyl)-4,4′,5,5′-tetra(dialkoxyphenyl)biimidazole, 2,2′-bis(2-chlorophenyl)-4,4′,5,5′-tetra(trialkoxyphenyl)biimidazole (for example, see Japanese Patent No. 48-38403 and Japanese Patent Laid-Open No. 62-174204), and an imidazole compound in which a phenyl group at the 4,4′,5,5′ position is substituted with a carboalkoxy group (for example, see Japanese Patent Laid-Open No. 7-10913). Among these, compounds represented by the following formula and mixtures thereof are preferable.

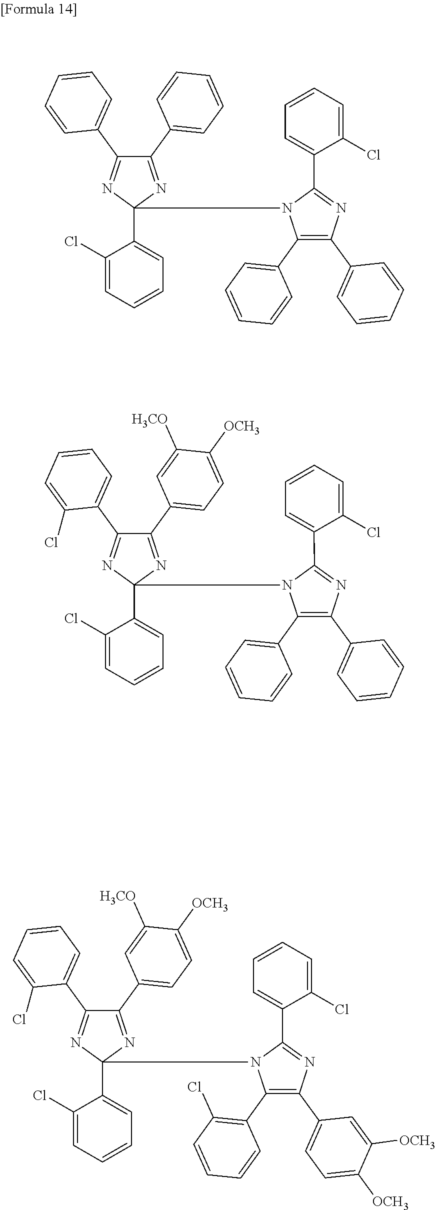 [SMILES: Clc1ccccc1-c1nc(-c2ccccc2)c(-c2ccccc2)n1C1(c2ccccc2Cl)N=C(c2ccccc2)C(c2ccccc2)=N1 ; COc1ccc(C2=NC(c3ccccc3Cl)(n3c(-c4ccccc4Cl)nc(-c4ccccc4)c3-c3ccccc3)N=C2c2ccccc2Cl)cc1OC ; COc1ccc(C2=NC(c3ccccc3Cl)(n3c(-c4ccccc4Cl)nc(-c4ccc(OC)c(OC)c4)c3-c3ccccc3Cl)N=C2c2ccccc2Cl)cc1OC]

Examples of the triazine compound include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxystyryl)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-diethylamino-2-methylphenyl)ethenyl]-1,3,5-triazine, and 2,4-bis(trichloromethyl)-6-[2-(3,4-dimethoxyphenyl)ethenyl]-1,3,5-triazine.

Examples of the acylphosphine oxide compound include 2,4,6-trimethylbenzoyldiphenylphosphine oxide.

Furthermore, examples of the polymerization initiator (D) include benzoin compounds such as benzoin, benzoin methyl ether, benzoin ethyl ether, benzoin isopropyl ether, and benzoin isobutyl ether; benzophenone compounds such as benzophenone, methyl o-benzoylbenzoate, 4-phenylbenzophenonne, 4-benzoyl-4′-methyldiphenyl sulfide, 3,3′,4,4′-tetra(tert-butylperoxycarbonyl)benzophenone, and 2,4,6-trimethylbenzophenone; quinone compounds such as 9,10-phenanthrene quinone, 2-ethylanthraquinone, and camphorquinone; 10-butyl-2-chloroacridone, benzyl, methyl phenylglyoxylate, and a titanocene compound. These examples may be used in combination with a polymerization initiation aid (D1) to be described later.

The content of the polymerization initiator (D) is preferably 0.1 to 20 parts by mass, more preferably 0.5 to 15 parts by mass, and still more preferably 1 to 12 parts by mass relative to 100 parts by mass of the total amount of the resin (B) and the polymerizable compound (C). When the content of the polymerization initiator (D) falls within the above-mentioned range, there is a tendency that the sensitivity is increased and that the time of exposure to light is shortened, resulting in the improvement in productivity of the color filter.

<Polymerization initiation aid (D1)>

The polymerization initiation aid (D1) is a compound to be used for accelerating polymerization of a polymerizable compound the polymerization of which has been started by the polymerization initiator, or a sensitizer. When the polymerization initiation aid (D1) is contained, the polymerization initiation aid (D1) is commonly used in combination with the polymerization initiator (D).

Examples of the polymerization initiation aid (D1) include 4,4′-bis(dimethylamino)benzophenone (common name: Michler's ketone), 4,4′-bis(diethylamino)benzophenone, 9,10-dimethoxyanthracene, 2,4-diethylthioxanthone, and N-phenylglycine.

When these polymerization initiation aids (D1) are used, the content of each aid (D1) is preferably 0.1 to 30 parts by mass, and more preferably 0.5 to 20 parts by mass relative to 100 parts by mass of the total amount of the resin (B) and the polymerizable compound (C). When the amount of the polymerization initiation aid (D1) falls within the above-mentioned range, there is a tendency that the colored pattern can be formed with higher sensitivity, resulting in improved productivity of the color filter.

### <Solvent (E)>

The solvent (E) is not particularly limited, and any solvent which has been used usually in the art can be used. Examples of the solvent (E) include an ester solvent (a solvent which contains —COO— but does not contain —O— in its molecule), an ether solvent (a solvent which contains —O— but does not contain —COO— in its molecule), an ether ester solvent (a solvent which contains —COO— and —O— in its molecule), a ketone solvent (a solvent which contains —CO— but does not contain —COO— in its molecule), an alcohol solvent (a solvent which contains OH but does not contain —O—, —CO— and —COO— in its molecule), an aromatic hydrocarbon solvent, an amide solvent, and dimethyl sulfoxide.

Examples of the ester solvent include methyl lactate, ethyl lactate, butyl lactate, methyl 2-hydroxy isobutanoate, ethyl acetate, n-butyl acetate, isobutyl acetate, pentyl formate, isopentyl acetate, butyl propionate, isopropyl butyrate, ethyl butyrate, butyl butyrate, methyl pyruvate, ethyl pyruvate, propyl pyruvate, methyl acetoacetate, ethyl acetoacetate, cyclohexanol acetate, and γ-butyrolactone.

Examples of the ether solvent include ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monobutyl ether, propylene glycol monomethyl ether, propylene glycol monoethyl ether, propylene glycol monopropyl ether, propylene glycol monobutyl ether, 3-methoxy-1-butanol, 3-methoxy-3-methylbutanol, tetrahydrofuran, tetrahydropyran, 1,4-dioxane, diethylene glycol dimethyl ether, diethylene glycol diethyl ether, diethylene glycol methyl ethyl ether, diethylene glycol dipropyl ether, diethylene glycol dibutyl ether, anisole, phenetol, and methyl anisole.

Examples of the ether ester solvent include methyl methoxyacetate, ethyl methoxyacetate, butyl methoxyacetate, methyl ethoxyacetate, ethyl ethoxyacetate, methyl 3-methoxypropionate, ethyl 3-methoxypropionate, methyl 3-ethoxypropionate, ethyl 3-ethoxypropionate, methyl 2-methoxypropionate, ethyl 2-methoxypropionate, propyl 2-methoxypropionate, methyl 2-ethoxy propionate, ethyl 2-ethoxypropionate, methyl 2-methoxy-2-methylpropionate, ethyl 2-ethoxy-2-methylpropionate, 3-butyl methoxyacetate, 3-methyl-3-butyl methoxyacetate, propylene glycol monomethyl ether acetate, propylene glycol monoethyl ether acetate, propylene glycol monopropyl ether acetate, ethylene glycol monomethyl ether acetate, ethylene glycol monoethyl ether acetate, diethylene glycol monoethyl ether acetate, and diethylene glycol monobutyl ether acetate.

Examples of the ketone solvent include 4-hydroxy-4-methyl-2-pentanone (diacetone alcohol), acetone, 2-butanone, 2-heptanone, 3-heptanone, 4-heptanone, 4-methyl-2-pentanone, cyclopentanone, cyclohexanone, and isophorone.

Examples of the alcohol solvent include methanol, ethanol, propanol, butanol, hexanol, cyclohexanol, ethylene glycol, propylene glycol, and glycerin.

Examples of the aromatic hydrocarbon solvent include benzene, toluene, xylene, and mesitylene.

Examples of the above amide solvent include N,N-dimethylformamide, N,N-dimethylacetamide, and N-methylpyrrolidone.

As the solvent (E), one or more types of solvent selected from the group consisting of an ether solvent, an ether ester solvent and a ketone solvent are preferably contained, an ether solvent and an ether ester solvent are more preferably contained, and a propylene glycol monomethyl ether and a propylene glycol monomethyl ether acetate are still more preferably contained.

The content rate of the solvent (E) is preferably 30 to 80% by mass, and more preferably 35 to 75% by mass, relative to the whole amount of the colored resin composition of the present invention. In other words, the solid content of the colored resin composition is preferably 20 to 70% by mass, and more preferably 25 to 65% by mass. When the content rate of the solvent (E) falls within the above-mentioned range, there is a tendency that the flatness during application becomes good and the color density of the color filter formed becomes not insufficient, resulting in the achievement of good displaying properties.

### <Leveling Agent (F)>

Examples of the leveling agent (F) include a silicone-based surfactant, a fluorine-based surfactant, and a silicone-based surfactant having a fluorine atom. These may have a polymerizable group at its side chain.

Examples of the silicone-based surfactant include a surfactant having a siloxane bond in its molecule. Specific examples thereof include Toray Silicone DC3PA, Toray Silicone SH7PA, Toray Silicone DC11PA, Toray Silicone SH21PA, Toray Silicone SH28PA, Toray Silicone SH29PA, Toray Silicone SH30PA, and Toray Silicone SH8400 (trade name: manufactured by Dow Corning Toray Co., Ltd.); KP321, KP322, KP323, KP324, KP326, KP340, and KP341 (manufactured by Shin-Etsu Chemical Co., Ltd.); and TSF400, TSF401, TSF410, TSF4300, TSF4440, TSF4445, TSF4446, TSF4452, and TSF4460 (manufactured by Momentive Performance Materials Inc.).

Examples of the fluorine-based surfactant include a surfactant having a fluorocarbon chain in its molecule. Specific examples thereof include Fluorad (registered trademark) FC430 and Fluorad FC431 (manufactured by Sumitomo 3M, Ltd.); Megafac (registered trademark) F142D, Megafac F171, Megafac F172, Megafac F173, Megafac F177, Megafac F183, Megafac F554, Megafac R30, and Megafac RS-718-K (manufactured by DIC Corporation); Eftop (registered trademark) EF301, Eftop EF303, Eftop EF351, and Eftop EF352 (manufactured by Mitsubishi Materials Electronic Chemicals Co., Ltd.); Surflon (registered trademark) 5381, Surflon 5382, Surflon SC101, and Surflon SC105 (manufactured by AGC Inc., (formerly Asahi Glass Co., Ltd.)); and E5844 (manufactured by Daikin Finechemical Laboratory).

Examples of the silicone-based surfactant having a fluorine atom include a surfactant having a siloxane bond and a fluorocarbon chain in its molecule. Specific examples thereof include Megafac (registered trademark) R08, Megafac BL20, Megafac F475, Megafac F477, and Megafac F443 (manufactured by DIC Corporation).

When the leveling agent (F) is contained, the content rate of the leveling agent (F) is preferably 0.0005 to 0.2% by mass, and more preferably 0.0008 to 0.1% by mass relative to the whole amount of the colored resin composition. Note that this content rate does not include the content rate of the pigment dispersant. When the content rate of the leveling agent (F) falls within the above-mentioned range, the flatness of the color filter can be improved.

### <Other Components>

If required, the colored resin composition of the present invention may contain an additive known in the art, such as a filler, other polymeric compounds, an adhesion promoter, an antioxidant, a light stabilizer, or a chain transfer agent.

### <Method for Producing Colored Resin Composition>

The colored resin composition of the present invention can be prepared by, for example, mixing, the colorant (A), the resin (B), and the polymerizable compound (C), and the polymerization initiator (D), as well as the solvent (E), the leveling agent (F) and other components to be used if required.

The colorant (A) may also be prepared using the above pigment dispersant. A desired colored resin composition can be prepared by mixing the pigment dispersant with the other components in such a manner that the concentration thereof is predetermined concentrations.

Further, the colored resin composition after mixing is preferably filtered with a filter having a pore size of about 0.01 to 10

### <Method for Producing Color Filter>

Examples of the method for producing the colored pattern from the colored resin composition of the present invention include a photolithography method, an inkjet method, and a printing method. Among these methods, a photolithography method is preferable. The photolithography method involves applying the colored resin composition onto a substrate, drying the substrate to form a coloring composition layer, and then exposing the coloring composition layer to light through a photomask for development. In the photolithography method, the photomask is not used during the exposure to light, and/or the coloring composition layer is not developed, whereby a colored coating film which is a cured product of the coloring composition layer can be formed. The thus formed colored pattern or the colored coating film is the color filter of the present invention.

Examples of the substrate to be used include glass substrates such as quartz glass, borosilicate glass, alumina silicate glass, and soda lime glass the surface of which has been coated with silica; resin substrates such as polycarbonate, poly(methyl methacrylate), and polyethylene terephthalate; silicon; and substrates on which aluminum, silver, or a silver/copper/palladium alloy thin film or the like has been formed. On these substrates, other color filter layer, a resin layer, a transistor, and a circuit and the like may be formed.

The formation of each color pixel using a photolithography method can be carried out using a known or conventional device or under known or conventional conditions. For example, the color pixel can be prepared in the following manner.

First, a colored resin composition is applied onto a substrate, and then dried by heat-drying (pre-baking) and/or drying under reduced pressure to remove volatile components such as a solvent from the composition, thereby producing a smooth coloring composition layer.

Examples of the application method include a spin coat method, a slit coat method, and a slit-and-spin coat method.

The temperature to be employed when heat-drying is carried out is preferably 30 to 120° C., and more preferably 50 to 110° C. The time for heating is preferably 10 seconds to 60 minutes, and more preferably 30 seconds to 30 minutes.

When drying under reduced pressure is carried out, the drying procedure is preferably carried out at a temperature range of 20 to 25° C. under a pressure of 50 to 150 Pa.

The film thickness of the coloring composition layer is not particularly limited, and may be selected appropriately depending on the desired film thickness of the color filter.

Next, the coloring composition layer is exposed to light through a photomask for forming a desired colored pattern. The pattern on the photomask is not particularly limited, and a pattern suitable for the intended application is used.

A light source to be used for the exposure to light is preferably a light source capable of generating light having a wavelength of 250 to 450 nm. For example, light having a wavelength of shorter than 350 nm may be cut with a filter capable of cutting light having this wavelength region, or light having a wavelength of around 436 nm, around 408 nm, or around 365 nm may be extracted selectively with a band-pass filter capable of extracting light having those wavelength region. Specific examples of the light source include a mercury lamp, a light-emitting diode, a metal halide lamp, and a halogen lamp. Further, the exposure amount on the basis of the wavelength of 365 nm is preferably 50 to 300 J/cm², more preferably 60 to 200 J/cm², and still more preferably 65 to 180 J/cm².

A light-exposing device such as a mask aligner and a stepper is preferably used because the device is capable of emitting parallel light beams uniformly over the whole area of the exposed surface and accurately aligning the photomask to the substrate having the coloring composition layer formed thereon.

A colored pattern is formed on the substrate by bringing the exposed coloring composition layer into contact with a developing solution to develop the coloring composition layer. By developing, an unexposed area in the coloring composition layer is dissolved in the developing solution and therefore removed. The developing solution is preferably an aqueous solution of an alkaline compound such as potassium hydroxide, sodium hydrogen carbonate, sodium carbonate, or tetramethylammonium hydroxide. The concentration of the alkaline compound in the aqueous solution is preferably 0.01 to 10% by mass, and more preferably 0.03 to 5% by mass. The developing solution may further contain a surfactant.

The developing method may be any of a paddle method, a dipping method, a spray method and the like. Furthermore, during the developing process, the substrate may be inclined at any angle.

After the developing process, the resultant product is preferably washed with water.

Furthermore, the resultant colored pattern is preferably subjected to post-baking. The temperature for post-baking for the formation of a color filter to be used for an organic EL display device may be 200° C. or lower, is preferably 170° C. or lower and more preferably 150° C. or lower. In the present invention, post-baking is preferably performed at temperatures of 130° C. or lower, for example. The lower limit of the temperature for post-baking is preferably 70° C. or higher, and more preferably 75° C. or higher. The time for post-baking is preferably 1 to 120 minutes, and more preferably 5 to 60 minutes.

The film thickness of a coating film after post-baking is, for example, preferably 3 μm or less, and more preferably 2.5 μm or less. The lower limit of the film thickness of a coating film is not particularly limited, and is usually 0.3 μm or more and may be 0.5 μm or more.

According to the colored resin composition of the present invention, a colored resin composition having good low temperature curability and thus being useful in production of a color filter suitable for an organic EL display device can be provided.

Further, the colored resin composition of the present invention is useful in preparation of a red color filter. The CIE chromaticity coordinates of the red color filter under conditions of a C light source and a 2° field of view are, for example, preferably within the range of 0.600≤x≤0.720, 0.280≤y≤0.360, more preferably within the range of 0.630≤x≤0.710, 0.290≤y≤0.340, and still more preferably within the range of 0.660≤x≤0.710, 0.290≤y≤0.330. With the x,y chromaticity coordinates within the above ranges, the closer the value of x is to 0.710, the better the color filter excellent in red color reproducibility can be produced, and thus this is still more preferable.

### EXAMPLES

Hereinafter, the present invention will be described in more detail with reference to Examples, but the present invention is not limited by these Examples. “Parts” refers to “parts by mass” and “%” refers to “% by mass”, unless otherwise specified.

Hereinafter, the structures of the compounds were confirmed by mass spectrometry (LC; model 1200, manufactured by Agilent, MASS; model LC/MSD, manufactured by Agilent) or elementary analysis (VARIO-EL; manufactured by Elementar).

### Synthetic Example 1

Into a flask equipped with a stirrer, a dropping funnel, a condenser, a thermometer, and a gas introducing tube, 276.8 g of propylene glycol monomethyl ether acetate was added, and then the mixture was stirred while replacing the air in the flask with nitrogen, so as to increase the temperature to 120° C. Then, a monomer mixture of 92.4 g (0.27 mol) of 2-ethyl hexyl acrylate, 184.9 g (0.70 mol) of glycidyl methacrylate and 12.3 g (0.03 mol) of dicyclopentanyl methacrylate, which had been supplemented with 35.3 g of t-butyl peroxy-2-ethyl hexanoate (polymerization initiator), was added dropwise via a dropping funnel over 2 hours into the flask. After the completion of dropwise addition, the mixture was further stirred at 120° C. for 30 minutes to perform copolymerization reaction, thereby generating an additive copolymer. Subsequently, a nitrogen atmosphere in the flask was replaced with air, 93.7 g (0.70 mol) of acrylic acid, 1.5 g of triphenyl phosphine (catalyst) and 0.8 g of methoquinone (MEHQ, polymerization inhibitor) were added to the above additive copolymer solution. Reaction was continued at 110° C. for 10 hours, thereby introducing a polymerizable unsaturated bond into the side chain of the polymer simultaneously with splitting of the epoxy group by the reaction of a glycidyl methacrylate-derived epoxy group with acrylic acid. Then, 24.2 g (0.13 mol) of a succinic anhydride was added to the reaction system, the reaction was continued at 110° C. for 1 hour, a hydroxy group resulting from the splitting of the epoxy group was reacted with the succinic anhydride to introduce a carboxy group into the side chain, and thus a copolymer (resin (B-1)) was obtained. Finally, 383.3 g of propylene glycol monomethyl ether acetate was added to the reaction solution, so that a resin (B-1) solution wherein the solid content concentration of the copolymer was 40% was obtained. The weight average molecular weight Mw of the thus generated copolymer was 6.3×10³, and the acid value was 34.3 mg-KOH/g in terms of solid content.

### (Preparation of Dispersion 1)

Pigment dispersant 1 was obtained by mixing the following components and sufficiently dispersing the pigment using a bead mill.

| | | |
|---|---|---|
| C.I. Pigment Red 269 (pigment) | 14.0 | parts |
| Acrylic pigment dispersant | 4.2 | parts |
| Acrylic pigment-dispersed resin (resin (B-1)) | 4.2 | parts |
| Propylene glycol monomethyl ether acetate | 69.8 | parts |
| Propylene glycol monomethyl ether | 7.8 | parts |

### (Preparation of Dispersion 2)

Pigment dispersant 2 was obtained by mixing the following components and sufficiently dispersing the pigment using a bead mill.

| | | |
|---|---|---|
| C.I. Pigment Yellow 139 (pigment) | 12.0 | parts |
| Acrylic pigment dispersant | 4.2 | parts |
| Acrylic pigment-dispersed resin (resin (B-1)) | 4.2 | parts |
| Propylene glycol monomethyl ether acetate | 74.8 | parts |
| Propylene glycol monomethyl ether | 4.8 | parts |

### (Preparation of Dispersion 3)

Pigment dispersant 3 was obtained by mixing the following components and sufficiently dispersing the pigment using a bead mill.

| | | |
|---|---|---|
| C.I. Pigment Violet 19 (pigment) | 13.0 | parts |
| Acrylic pigment dispersant | 3.7 | parts |
| Acrylic pigment-dispersed resin (resin (B-1)) | 4.3 | parts |
| Propylene glycol monomethyl ether acetate | 76.6 | parts |
| Propylene glycol monomethyl ether | 2.5 | parts |

### (Preparation of Dispersion 4)

Pigment dispersant 4 was obtained by mixing the following components and sufficiently dispersing the pigment using a bead mill.

| | | |
|---|---|---|
| C.I. Pigment Red 254 (pigment) | 10.8 | parts |
| Acrylic pigment dispersant | 3.8 | parts |
| Acrylic pigment-dispersed resin (resin (B-1)) | 5.5 | parts |
| Propylene glycol monomethyl ether acetate | 77.1 | parts |
| Propylene glycol monomethyl ether | 2.9 | parts |

### (Preparation of Dispersion 5)

Pigment dispersant 5 was obtained by mixing the following components and sufficiently dispersing the pigment using a bead mill.

| | | |
|---|---|---|
| C.I. Pigment Red 291 (pigment) | 13.0 | parts |
| Acrylic pigment dispersant | 3.5 | parts |
| Acrylic pigment-dispersed resin (resin (B-1)) | 4.0 | parts |
| Propylene glycol monomethyl ether acetate | 74.8 | parts |
| Propylene glycol monomethyl ether | 4.7 | parts |

### (Preparation of Dispersion 6)

Pigment dispersant 6 was obtained by mixing the following components and sufficiently dispersing the pigment using a bead mill.

| | | |
|---|---|---|
| C.I. Pigment Red 177 (pigment) | 14.8 | parts |
| Acrylic pigment dispersant | 5.7 | parts |
| Acrylic pigment-dispersed resin (resin (B-1)) | 1.4 | parts |
| Propylene glycol monomethyl ether acetate | 78.0 | parts |

### Examples 1 to 8

### (Preparation of Colored Resin Composition)

Each colored resin composition was obtained by mixing components shown in Tables 1 and 2.

TABLE 1

| Unit (parts) | Example 1 | Example 2 |
|---|---|---|
| Dispersion 1 | 12.58 | 19.97 |
| Dispersion 2 | 16.78 | 19.60 |
| Dispersion 3 | 20.63 | 10.00 |
| Resin (B) | 0.61 | 0.64 |
| Polymerizable compound (C) | 1.69 | 1.67 |
| Polymerization initiator (D) | 0.25 | 0.25 |
| leveling agent (F) | 0.001 | 0.001 |
| Solvent (E) | 47.45 | 47.86 |

TABLE 2

| Unit (parts) | Example 3 | Example 4 | Example 5 | Example 6 | Example 7 | Example 8 |
|---|---|---|---|---|---|---|
| Dispersion 2 | 11.26 | 7.75 | 13.59 | 11.79 | 12.90 | 11.15 |
| Dispersion 3 | 20.00 | 10.00 | 20.00 | 10.00 | 20.00 | 10.00 |
| Dispersion 4 | 23.42 | 39.47 | — | — | — | — |
| Dispersion 5 | — | — | 17.20 | 28.90 | — | — |
| Dispersion 6 | — | — | — | — | 15.66 | 25.88 |
| Resin (B) | 0.41 | 0.42 | 0.62 | 0.65 | 0.95 | 1.21 |
| Polymerizable | 1.24 | 0.81 | 1.72 | 1.73 | 1.62 | 1.57 |
| compound (C) | | | | | | |
| Polymerization | 0.25 | 0.24 | 0.26 | 0.26 | 0.24 | 0.24 |
| initiator (D) | | | | | | |
| leveling agent (F) | 0.013 | 0.013 | 0.013 | 0.013 | 0.013 | 0.013 |
| Solvent (E) | 43.41 | 41.29 | 46.59 | 46.65 | 48.60 | 49.95 |

Each component shown in Tables 1 and 2 is as follows.

Resin (B): resin (B-1) (in terms of solid content)

Polymerizable compound (C): dipentaerythritol polyacrylate (“A9550”, manufactured by Shin-Nakamura Chemical Co., Ltd., in terms of solid content)

Polymerization initiator (D): Irgacure (registered trademark) OXE-03; manufactured by BASF Corporation; compound represented by formula (d1-x)

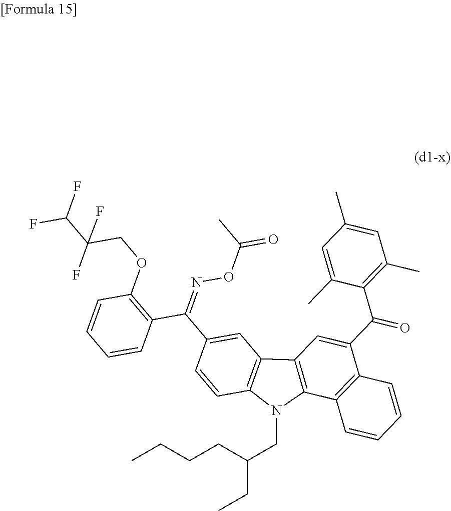 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

Leveling agent (F): polyether-modified silicone oil (SH8400; manufactured by Dow Corning Toray Co., Ltd., propylene glycol monomethyl ether acetate solution with a solid content of 10%)

Solvent (E): propylene glycol monomethyl ether acetate

### (Preparation of Colored Pattern)

Onto a 5-cm square glass substrate (Eagle 2000; manufactured by Corning Incorporated), a colored resin composition was applied by a spin coat method so that the final film thickness was 2.5 μm, and then prebaked at 70° C. for 1 minute, thereby forming a coloring composition layer. After cooling, the coloring composition layer was subjected to light irradiation while keeping the distance of 100 μm between the substrate having the coloring composition layer formed thereon and a photomask made of quartz glass in an exposure amount (basis: 365 nm) of 100 mJ/cm² under an air atmosphere using an exposure device (TME-150RSK; manufactured by Topcon Corporation). After irradiation, post-baking was performed using a hot plate at 100° C. for 15 minutes, thereby obtaining a colored plate having the colored pattern formed thereon.

### (Spectral Evaluation)

The thus obtained colored plate having the colored pattern formed thereon was subjected to spectral measurement using a color measurement device (V-630; manufactured by JASCO Corporation), thereby evaluating color properties. The results of xy chromaticity coordinates (x,y) based on the CIE XYZ colorimetric system are shown in Tables 3 and 4. It was demonstrated that when x was 0.600 or more and 0.720 or less, and γ was 0.280 or more and 0.360 or less, the larger the value of x (particularly the closer the value of x to 0.710), the better the red color reproducibility.

### (Preparation of Colored Coating Film)

Onto a 5-cm square glass substrate (Eagle 2000; manufactured by Corning Corporation), a colored resin composition was applied by a spin coat method so that the final film thickness was 1.5 μm, and then prebaked at 70° C. for 1 minute, thereby forming a coloring composition layer. After cooling, the coloring composition layer was subjected to light irradiation in an exposure amount (basis: 365 nm) of 200 mJ/cm² under an air atmosphere using an exposure device (TME-150RSK; manufactured by Topcon Corporation). After irradiation, post-baking was performed using a hot plate at 100° C. for 15 minutes, thereby obtaining a colored plate having the coloring coating film formed thereon.

In any of Examples 1 to 8, even in the case of post-baking at a temperature as low as 100° C., curing was successfully performed without generating uncured parts and without leaving any stickiness on the surfaces, and good low temperature curability was exhibited.

### (Evaluation of Solvent Resistance)

The thus obtained colored plate having the colored coating film formed thereon was immersed in propylene glycol monomethyl ether acetate (PGMEA) or propylene glycol monomethyl ether (PGME) for 5 minutes, and then subjected to spectral measurement before and after immersion using a color measurement device (V-630; manufactured by JASCO Corporation). The results representing color changes due to immersion by ΔEab are shown in Tables 3 and 4. The results mean that the lower the value of ΔEab, the smaller the color change, demonstrating good solvent resistance.

TABLE 3

| | |
|---|---|
| | Solvent |
| Color properties | resistance ΔEab |

| | x | y | PGMEA | PGME |
|---|---|---|---|---|
| Example 1 | 0.694 | 0.302 | 0.5 | 1.3 |
| Example 2 | 0.692 | 0.307 | 0.2 | 1.2 |

TABLE 4

Color properties

| | x | y |
|---|---|---|
| Example 3 | 0.698 | 0.301 |
| Example 4 | 0.690 | 0.310 |
| Example 5 | 0.698 | 0.301 |
| Example 6 | 0.690 | 0.309 |
| Example 7 | 0.696 | 0.302 |
| Example 8 | 0.692 | 0.306 |

1. A colored resin composition comprising a colorant, a resin, a polymerizable compound, and a polymerization initiator, wherein
the colorant is composed of only a pigment,
the pigments include C.I. Pigment Violet 19, a red pigment and a yellow pigment.

2. The colored resin composition according to claim 1, comprising at least one red pigment selected from C.I. Pigment Red 177, C.I. Pigment Red 254, C.I. Pigment Red 269 and C.I. Pigment Red 291.

3. The colored resin composition according to claim 1, wherein the red pigments include C.I. Pigment Red 269.

4. The colored resin composition according to claim 1, wherein the yellow pigments include C.I. Pigment Yellow 139.

5. A color filter, which is formed of the colored resin composition according to claim 1.

6. An organic EL display device, comprising the color filter according to claim 5.
